(19) United States
(12) Patent Application Publication
(10) Pub. No.: US 2002/0153524 A1
(43) Pub. Date: Oct. 24, 2002

(54) Structure and method for fabricating semiconductor structures and devices utilizing perovskite stacks

(75) Inventors: Zhiyi Yu, Gilbert, AZ (US); Ravindranath Droopad, Chandler, AZ (US); William J. Ooms, Prescott, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola Inc.

(21) Appl. No.: 09/838,273

(22) Filed: Apr. 19, 2001

(51) Int. Cl. H01L 29/12; H01L 21/00; H01L 27/12; H01L 31/0392

(52) U.S. Cl. 257/43; 438/85; 438/86; 438/104; 438/754; 257/347; 438/149; 257/352

(57) ABSTRACT

A high quality semiconductor structure includes a monocrystalline substrate and a perovskite stack overlying the substrate. The perovskite stack may be formed of a first accommodating layer formed of a first perovskite oxide material having a first lattice constant. A second accommodating layer is formed on the first accommodating layer. The second accommodating layer is formed of a second perovskite oxide material having a second lattice constant which is different from the first lattice constant of the first accommodating layer. A monocrystalline material layer is formed overlying the second accommodating layer. A strain is effected at the interface between the perovskite stack and the substrate, at the interface between the perovskite stack and the monocrystalline material layer and/or at the interface between the first accommodating layer and the second accommodating layer. The strain reduces defects in the monocrystalline material layer and results in reduced Schottky leakage current.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a high-quality monocrystalline material layer overlying a perovskite stack.

### BACKGROUND OF THE INVENTION

Semiconductor devices typically include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films, such as GaAs, on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of the monocrystalline material to be of low crystalline quality.

In an effort to achieve high crystalline quality in monocrystalline material layers, growing such layers on silicon substrates using a single perovskite layer, such as a SrTiO₃ layer, between the substrate and the monocrystalline material layer has been proposed. Typically, in addition to achieving a high crystalline-quality monocrystalline material layer, it is desirable to prevent or at least limit leakage current from the substrate to the monocrystalline material layer. However, the single perovskite layer is not able to limit or reduce the leakage current for two reasons. First, stoichiometric perovskite materials typically are semiconducting due to oxygen vacancies. Second, the interface between the silicon substrate and the perovskite layer has a negligible conduction band offset such that the Schottky electron leakage current is intrinsically high.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material, while exhibiting minimal leakage current.

Accordingly, a need exists for a semiconductor structure that provides a high quality monocrystalline film or layer over another stress-relieving layer and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having a grown monocrystalline film the same crystal orientation as an underlying substrate. This monocrystalline material layer may be comprised of a semiconductor material, a compound semiconductor material, and other types of material such as metals and non-metals.

In addition, a need exists for a semiconductor structure which has a high quality monocrystalline material layer and which exhibits low electron leakage current.

A further need exists for a semiconductor structure that provides a perovskite stack overlying a monocrystalline substrate for the formation of quality semiconductor structures, devices and integrated circuits.

### BRIEF DESCRIPTION OF THE DRAWINGS

The present invention is illustrated by way of example and not limitation in the accompanying figures, in which like references indicate similar elements, and in which:

FIGS. 1-4 illustrate schematically, in cross section, device structures in accordance with exemplary embodiments of the invention;

FIG. 5 illustrates graphically the relationship between maximum attainable film thickness and lattice mismatch between a host crystal and a grown crystalline overlayer;

FIGS. 6A-6D illustrate schematically, in cross section, the formation of a device structure in accordance with another embodiment of the invention; and

FIGS. 7A-7C illustrates schematically, in cross section, the formation of yet another embodiment of a device structure in accordance with the invention.

Skilled artisans will appreciate the elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

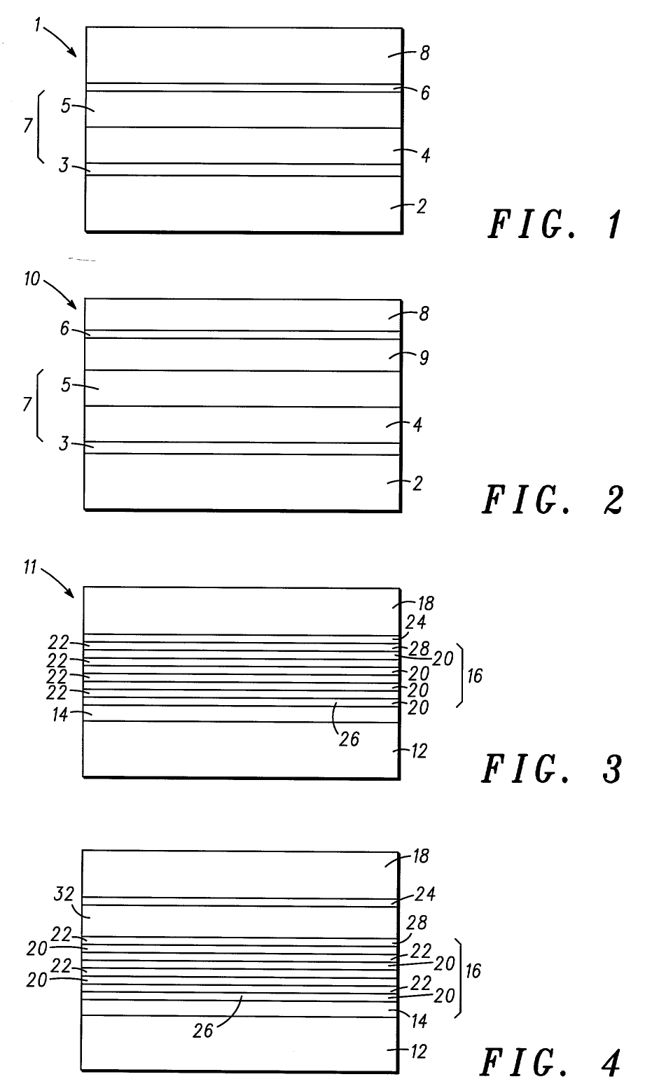

FIG. 1 illustrates schematically, in cross section, a structure 1 in accordance with an exemplary embodiment of the present invention. Semiconductor structure 1 includes a monocrystalline substrate 2, a perovskite stack 7 comprising layers of monocrystalline material, and a monocrystalline material layer 8. In this context, the term “monocrystalline” shall have the meaning commonly used within the semiconductor industry. The term shall refer to materials that are a single crystal or that are substantially a single crystal and shall include those material having a relatively small number of defects such as dislocations and the like as are commonly found in the substrates of silicon or germanium or mixtures of silicon and germanium and epitaxial layers of such materials commonly found in the semiconductor industry.

In accordance with one embodiment of the invention, structure 1 may also include an amorphous intermediate layer 3 positioned between substrate 2 and perovskite stack 7. In another embodiment of the invention, structure 1 may also include a template layer 6 between perovskite stack 7 and monocrystalline material layer 8. As will be explained more fully below, the template layer may help to initiate the growth of the monocrystalline material layer on the perovskite stack. The amorphous intermediate layer 3 may also help to relieve the strain in the perovskite stack and, by doing so, aids in the growth of the high crystalline quality perovskite stack.

Substrate 2, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 2 is a wafer containing silicon or germanium, and most preferably is a high quality monocrystalline silicon wafer as used in the semiconductor industry. Substrate 2 may optionally include a plurality of material layers such that the composite substrate may be tailored to the quality, performance, and manufacturing requirements of a variety of semiconductor device applications.

In another embodiment of the invention, substrate 2 may comprise a (001) Group IV material that has been off-cut towards a (110) direction. The growth of materials on a miscut Si (001) substrate is known in the art. For example, U.S. Pat. No. 6,039,803, issued to Fitzgerald et al. on Mar. 21, 2000, which patent is herein incorporated by reference, is directed to growth of silicon-germanium and germanium layers on miscut Si (001) substrates. Substrate 2 may be off-cut in the range of from about 2 degrees to about 6 degrees towards the (110) direction. A miscut Group IV substrate reduces dislocations and results in improved quality of subsequently grown layer 8.

Perovskite stack 7 may include a first accommodating layer 4 and a second accommodating layer 5. First accommodating layer 4 may comprise a monocrystalline perovskite oxide material selected for its crystalline (i.e., lattice) compatibility with the underlying substrate and/or the subsequently grown monocrystalline material layer 8. In an exemplary embodiment, layer 4 may comprise an alkaline earth metal titanate, such as, for example, barium titanate (BaTiO₃), strontium titanate (SrTiO₃), or barium strontium titanate (Sr_{z}Ba_{1-z}TiO₃), or another suitable perovskite oxide material having a thickness in the range of from about 4 to about 50 angstroms. Preferably, first accommodating layer 4 is formed of SrTiO₃ and has a thickness in the range of approximately 8-20 angstroms. Layer 4 may also comprise, for example, metal oxides such as the alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride and boron nitride may also be used for the additional buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

In accordance with another embodiment of the invention, structure 1 may also include an amorphous intermediate layer 3 positioned between substrate 2 and first accommodating layer 4 of perovskite stack 7. In accordance with one embodiment of the invention, amorphous intermediate layer 3 is grown on substrate 2 at the interface between substrate 2 and the growing first accommodating layer 4 of perovskite 7 by the oxidation of substrate 2 during the growth of layer 4. The amorphous intermediate layer helps to relieve the strain that might otherwise occur in the monocrystalline first accommodating layer 4 as a result of differences in the lattice constants of the substrate and layer 4 and, by doing so, aids in the growth of a high crystalline quality monocrystalline layer 4. High crystalline quality growth of first accommodating layer 4 further permits high quality crystalline quality growth in a subsequently grown second accommodating layer 5, and, hence, monocrystalline material layer 8.

Perovskite stack 7 also includes a second accommodating layer 5. Second accommodating layer 5 may comprise a monocrystalline perovskite oxide material selected for its crystalline (i.e., lattice) compatibility with monocrystalline material layer 8. Second accommodating layer 5 may be formed of any of those compounds previously described with reference to layer 4 and having a crystalline lattice constant that is different than the lattice constant of layer 4. As used herein, lattice constant refers to the distance between atoms of a cell measured in the plane of a surface. For example, if first accommodating layer 4 is formed of SrₓBa₁₋ₓTiO₃ where 0≦x≦1, second accommodating layer 5 may comprise Sr_{y}Ba_{1-y}TiO₃ (where y is not equal to x), which has a different lattice constant than SrₓBa₁₋ₓTiO₃. Preferably, when first accommodating layer 4 is formed of SrTiO₃, second accommodating layer 5 is formed of BaTiO₃. Second accommodating layer 5 may have a thickness in the range of from about 4 to about 50 angstroms, but is preferably 8 to 20 angstroms in thickness. Perovskite stack 7 preferably has a total thickness in the range of from about 20 angstroms to about 1000 angstroms and more preferably has a thickness in the range of from about 20 angstroms to 50 angstroms.

The relative thinness of first and second accommodating layers 4 and 5 and the difference in lattice constants of these layers may result in strain at the interface of substrate 2 and perovskite stack 7, between the first accommodating layer 4 and second accommodating layer 5 of perovskite stack 7, and/or between monocrystalline material layer 8 and second accommodating layer 5. This strain aids in localizing, deflecting or bending defects within the first and second accommodating layers 4 and 5, aiding in the growth of a high quality monocrystalline material layer 8. In addition, the strain serves to reduce and/or eliminate Schottky leakage current.

The material for monocrystalline material layer 8 can be selected as desired, for a particular structure or application. For example, the monocrystalline material of layer 8 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe) and the like. However, monocrystalline material layer 8 may also comprise other semiconductor materials, metals, or non-metal materials which are used in the formation of semiconductor structures, devices and/or integrated circuits.

Appropriate materials for template 6 are discussed below. Suitable template materials chemically bond to the surface of second accommodating layer 5 at selected sites and provide sites for the nucleation of the epitaxial growth of monocrystalline material layer 8. When used, template layer 6 has a thickness ranging from about 1 to about 10 monolayers.

FIG. 2 illustrates in cross section, a portion of a semiconductor structure 10 in accordance with a further embodiment of the invention. Structure 10 is similar to the previously described semiconductor structure 1, except that an additional buffer layer 9 is positioned between second accommodating layer 5 and template layer 6. Additional buffer layer 9 may be formed of a monocrystalline oxide or nitride material. While second accommodating layer 5 may be closely lattice matched to monocrystalline material layer 8, lattice differences between second accommodating layer 5 and monocrystalline material layer 8 may remain. Additional buffer layer 9 may serve to provide additional lattice compensation between second accommodating layer 5 and monocrystalline material layer 8.

Additional buffer layer 9 is preferably a monocrystalline oxide or nitride material selected for its crystalline compatibility with the overlying monocrystalline material layer 8. For example, the material could be an oxide or nitride having a lattice structure closely matched to second accommodating layer 5 and to the subsequently applied monocrystalline material layer 8. Materials that are suitable for the additional buffer layer include metal oxides such as the alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride and boron nitride may also be used for the additional buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

FIG. 3 illustrates, in cross section, another exemplary embodiment of the present invention. As shown in FIG. 3, a semiconductor structure 11 is similar to structure 1. Structure 11 includes a substrate 12, a perovskite stack 16 and a monocrystalline material layer 18. In a further embodiment, structure 11 may include an amorphous intermediate layer 14 between substrate 12 and a first layer 26 of perovskite stack 16. In yet a further embodiment, structure 11 may include a template layer 24 formed between a last layer 28 of perovskite stack 16 and monocrystalline material layer 18. Substrate 12 may be formed of the same materials as described above for substrate 2 with reference to FIG. 1, but is preferably formed of silicon. Monocrystalline material layer 18 may be formed of the same materials as described above for monocrystalline material layer 8 and amorphous intermediate layer 14 may be formed of the same materials as described above for amorphous intermediate layer 3.

Perovskite stack 16 may include a predetermined number of alternating first accommodating layers 20 and second accommodating layers 22. First accommodating layers 20 may comprise a monocrystalline perovskite oxide material selected for its crystalline (i.e., lattice) compatibility with the underlying substrate and/or the subsequently grown monocrystalline material layer 18. First accommodating layers 20 may be formed of the same materials as described above for first accommodating layer 4 and may have a thickness in the range of from about 4 to about 50 angstroms. Preferably, first accommodating layers 20 are formed of SrTiO₃ and have a thickness in the range of from about 8 to 20 angstroms.

Similarly, second accommodating layers 22 may be formed of a monocrystalline perovskite oxide material selected for its crystalline (i.e., lattice) compatibility with monocrystalline material layer 18. Second accommodating layers 22 may be formed of the same materials as described above for second accommodating layer 5, with lattice constants that are different from the lattice constants of first accommodating layers 20. For example, if first accommodating layers 20 are formed of SrTiO₃, second accommodating layers 22 may be formed of BaTiO₃. Second accommodating layers 22 may have a thickness in the range of from about 4 to about 50 angstroms but, preferably, have a thickness in the range of from about 8 to about 20 angstroms.

Perovskite stack 16 may have any suitable number of first and second accommodating layers but preferably has a total thickness in the range of from about 20 angstroms to about 1000 angstroms and more preferably has a thickness in the range of from about 40 angstroms to about 80 angstroms. Further, while perovskite stack 16 may have first accommodating layers 20 and second accommodating layers 22 that differ in thickness, perovskite stack 16 may also be in the form of a superlattice, with a uniform period of layers throughout the stack. With differing lattice constants between the alternating layers of perovskite stack 16, and with the relative thinness of the alternating layers, strain results between and within the various layers, at the interface between stack 16 and substrate 12, and at the interface between stack 16 and monocrystalline material layer 18. This strain aids in localizing, deflecting or bending defects within the various layers of stack 16, aiding in the growth of a high quality monocrystalline material layer 18. While the layers of stack 16 may range in thickness, the layers should not be so thick that the layers are permitted to relax, thereby reducing the strain and generating defects.

FIG. 4 illustrates, in cross section, a portion of a semiconductor structure 30 in accordance with a further embodiment of the invention. Structure 30 is similar to the previously described semiconductor structure 11, except that an additional buffer layer 32 is positioned between last layer 28 of perovskite stack 16 and template layer 24. The additional buffer layer may be formed of a monocrystalline oxide or nitride material. While second accommodating layers 22 may be closely lattice matched to monocrystalline material layer 18, lattice differences between the last layer 28 of second accommodating layers 22 and monocrystalline material layer 18 may remain. Additional buffer layer 32 may serve to provide additional lattice compensation between layer 28 and monocrystalline material layer 18.

Additional buffer layer 32 is preferably a monocrystalline oxide or nitride material selected for its crystalline compatibility with the overlying monocrystalline material layer 18. For example, the material could be an oxide or nitride having a lattice structure closely matched to the last layer 28 of perovskite stack 16 and to the subsequently applied monocrystalline material layer 18. Materials that are suitable for the additional buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the additional buffer layer.

The following non-limiting, illustrative examples illustrate various combinations of materials useful in structures 11 and 30 in accordance with various alternative embodiments of the invention. These examples are merely illustrative, and it is not intended that the invention be limited to these illustrative examples.

### EXAMPLE 1

In accordance with one exemplary embodiment of the invention, monocrystalline substrate 12 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, first accommodating layers 20 are monocrystalline layers of SrₓBa₁₋ₓTiO₃, where x ranges from 0 to 1. The value of x is selected to obtain one or more lattice constants closely matched to the corresponding lattice constant of the subsequently formed layer 18. The thickness of first accommodating layers 20 are in the range of from about 8 to about 20 angstroms. The amorphous intermediate layer 14 is a layer of silicon oxide (SiOₓ) formed at the interface between the silicon substrate and the first layer 26 of the first accommodating layers 20.

Second accommodating layers 22 are monocrystalline layers of Sr_{y}Ba_{1-y}TiO₃, where y does not equal x. The value of y may be selected to obtain one or more lattice constants that are even more closely matched to the corresponding lattice constants of subsequently formed layer 18 than those of first accommodating layers 20. The thickness of second accommodating layers 22 are in the range of from about 8 to about 20 angstroms. Perovskite stack 16 preferably has a thickness of from about 40 angstroms to about 80 angstroms.

In accordance with this embodiment of the invention, monocrystalline material layer 18 is a compound semiconductor layer of gallium arsenide (GaAs) or aluminum gallium arsenide (AlGaAs) having a thickness of about 1 nm to about 100 micrometers and preferably a thickness of about 0.5 to about 10 micrometers. The thickness generally depends on the application for which the layer is being prepared. To facilitate the epitaxial growth of the gallium arsenide or aluminum gallium arsenide on the last layer of second accommodating layers 22, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

This embodiment of the invention is an example of structure 30 illustrated in FIG. 4. Substrate 12, perovskite stack 16 and monocrystalline material layer 18 can be similar to those described in example 1. In addition, an additional buffer layer 32 serves to alleviate any strains that might result from a mismatch of the crystal lattice of the last layer 28 of perovskite stack 16 and the lattice of the monocrystalline material 18. Buffer layer 32 can be a layer of strontium titanate (SrTiO₃), barium titanate (BaTiO₃) or strontium barium titanate (SrₓBa₁₋ₓTiO₃, where x ranges from 0 to 1) or a strain-compensated superlattice formed of at least one of these materials. In accordance with one aspect of this embodiment, additional buffer layer 32 includes SrTiO₃. Buffer layer 32 can have a thickness of about 1-50 nm and preferably has a thickness of about 1-5 nm. The template for this structure can be the same of that described in example 1.

Referring again to FIGS. 1-4, substrate 12 is a monocrystalline substrate such as a monocrystalline silicon or gallium arsenide substrate. The crystalline structure of the monocrystalline substrate is characterized by a lattice constant and by a lattice orientation. In similar manner, first accommodating layer 4 and first accommodating layers 20 are also formed of a monocrystalline material and the lattice of that monocrystalline material is characterized by a lattice constant and a crystal orientation. The lattice constants of the first accommodating layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer. Similarly, the crystalline structure of second accommodating layer 5 and the second accommodating layers 22 are also characterized by a lattice constant and by a lattice orientation that are closely matched to those of the monocrystalline material layer 18.

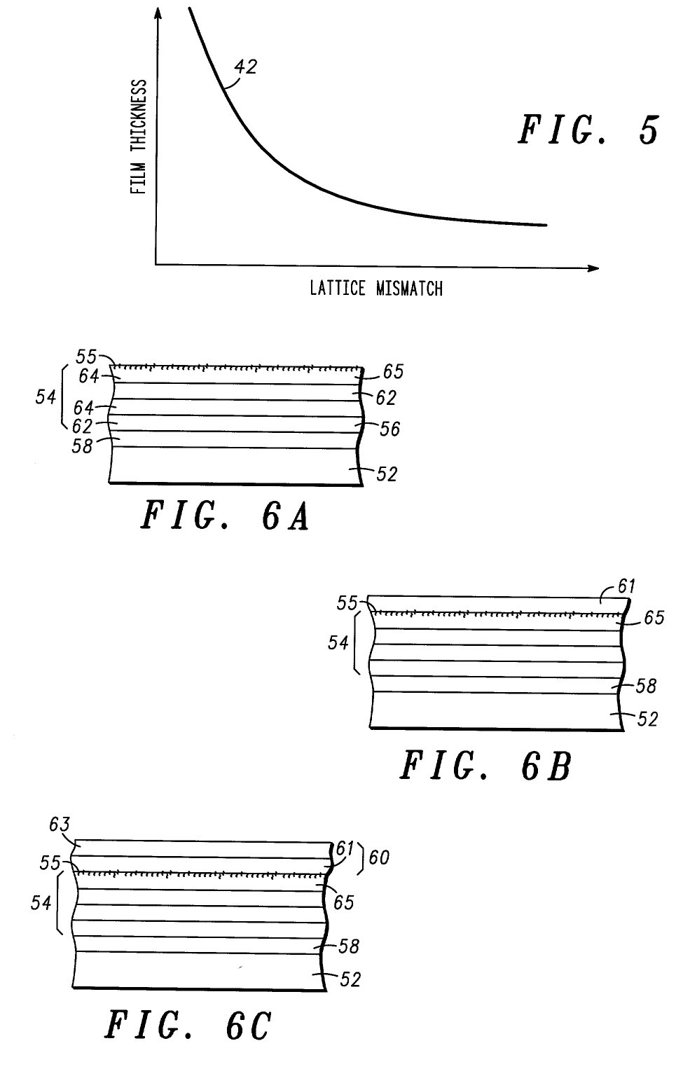

FIG. 5 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

The following example illustrates a process, in accordance with one embodiment of the invention, for fabricating a semiconductor structure such as the structures depicted in FIGS. 3 and 4. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, offcut about 2°-6° off axis towards the (110) direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface may exhibit an ordered 2×1 structure. If an ordered 2×1 structure has not been achieved at this stage of the process, the structure may be exposed to additional strontium until an ordered 2×1 structure is obtained. The ordered structure forms a template for the ordered growth of an overlying layer of a monocrystalline oxide. This template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the substrate by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered crystalline structure of the underlying substrate.

After the strontium titanate layer has been grown to the desired thickness, preferably 8 to 20 angstroms, a layer of barium titanate is grown on the strontium titanate layer by MBE. This MBE process is initiated by opening shutters in the MBE apparatus to expose barium, titanium and oxygen sources.

After the barium titanate layer has been grown to the desired thickness, preferably 8 to 20 angstroms, additional strontium titanate layers and barium titanate layers may be grown in an alternating manner using the above described process. The number of strontium titanate layers and barium titanate layers may be selected, and the thickness of the perovskite stack may be grown, as suitable for a desired semiconductor device application.

After the perovskite stack has been grown to the desired thickness, the monocrystalline perovskite stack is capped by a template layer that is conducive to the subsequent growth of an epitaxial layer of a desired monocrystalline material. For example, for the subsequent growth of a monocrystalline compound semiconductor material layer of gallium arsenide, the MBE growth of the last monocrystalline layer of the perovskite stack can be capped by terminating the growth with 1-2 monolayers of titanium, 1-2 monolayers of titanium-oxygen, 1-2 monolayers of strontium-oxygen if the last layer of the perovskite stack is strontium titanate or, if the last layer is formed of barium titanate, with 1-2 monolayers of barium-oxygen. Following the formation of this capping layer, arsenic is deposited to form a Ti—As bond, a Ti—O—As bond, Sr—O—As bond, or a Ba—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga or Ba—O—Ga bond, and arsenic is subsequently introduced with the gallium to form the GaAs.

The structure illustrated in FIG. 4 can be formed by the process discussed above with the addition of an additional buffer layer deposition step. The buffer layer is formed overlying the perovskite stack before the deposition of the template layer. The buffer layer may be grown to a desired thickness by a process similar to the process used to grow the strontium titanate layer or barium titanate layer described above.

The process described above illustrates a process for forming a semiconductor structure including a silicon substrate, an overlying perovskite stack and a monocrystalline material layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown.

Each of the variations of the monocrystalline material layer and the perovskite stack uses an appropriate template for initiating the growth of the monocrystalline material layer. For example, if the last layer of the perovskite stack is strontium titanate, the oxide can be capped with a layer of strontium or strontium and oxygen. If the last layer is formed of barium titanate, the barium titanate can be capped with a layer of barium or barium and oxygen. Each of these depositions can be followed by the deposition of arsenic or phosphorus to react with the capping material to form a template for the deposition of a monocrystalline material layer.

The formation of a device structure in accordance with another embodiment of the invention is illustrated schematically in cross section in FIGS. 6A-6D. Like the previously described embodiments referred to in FIGS. 1-4, this embodiment of the invention involves the process of forming a compliant substrate utilizing the epitaxial growth of single crystal oxides, such as the formation of a perovskite stack previously described with reference to FIGS. 1 and 3 and an additional buffer layer previously described with reference to FIGS. 2 and 4, and the formation of a template layer. However, the embodiment illustrated in FIGS. 6A-6D utilizes a template that includes a surfactant to facilitate layer-by-layer monocrystalline material growth.

Turning now to FIG. 6A, a perovskite stack 54 is formed overlying a substrate 52. An amorphous intermediate layer 58 may be grown on substrate 52 at the interface between substrate 52 and a growing first layer 56 of first accommodating layers 62 of perovskite stack 54 by the oxidation of substrate 52 during the growth of first layer 56. First accommodating layers 62 are preferably formed of a monocrystalline crystal oxide material such as a monocrystalline layer of SrₓBa₁₋ₓTiO₃, where x ranges from 0 to 1. However, layers 62 may also comprise any of those compounds previously described with reference to first accommodating layer 4 and first accommodating layers 20 in FIGS. 1-4. Alternating layers of second accommodating layers 64 and first accommodating layers 62 are subsequently grown to form perovskite stack 54. Second accommodating layers 64 are preferably formed of a monocrystalline crystal oxide material with a lattice constant different from the lattice constant of first accommodating layers 62. For example, when first accommodating layers 62 are formed of SrₓBa₁₋ₓTiO₃, second accommodating layers 64 may be formed of Sr_{y}Ba_{1-y}TiO₃, where y is not equal to x.

A top layer 65 of perovskite stack 54 is grown with a strontium (Sr) terminated surface represented in FIG. 6A by hatched line 55 which is followed by the addition of a template layer 60 which includes a surfactant layer 61 and capping layer 63 as illustrated in FIGS. 6B and 6C. Surfactant layer 61 may comprise, but is not limited to, elements such as Al, Bi, In and Ga, but will be dependent upon the composition of layer 65 and the overlying layer of monocrystalline material for optimal results. On one exemplary embodiment, aluminum (Al) is used for surfactant layer 61 and functions to modify the surface and surface energy of layer 65. Preferably, surfactant layer 61 is epitaxially grown to a thickness of one to two monolayers over layer 65 as illustrated in FIG. 6B by way of MBE, although other epitaxial process may also be performed including CVD, MOCVD, MEE, ALE, PVD, CSD, PLD, or the like.

Surfactant layer 61 is then exposed to a Group V element such as arsenic, for example, to form capping layer 63, as illustrated in FIG. 6C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, or the like to form the final structure illustrated in FIG. 6D.

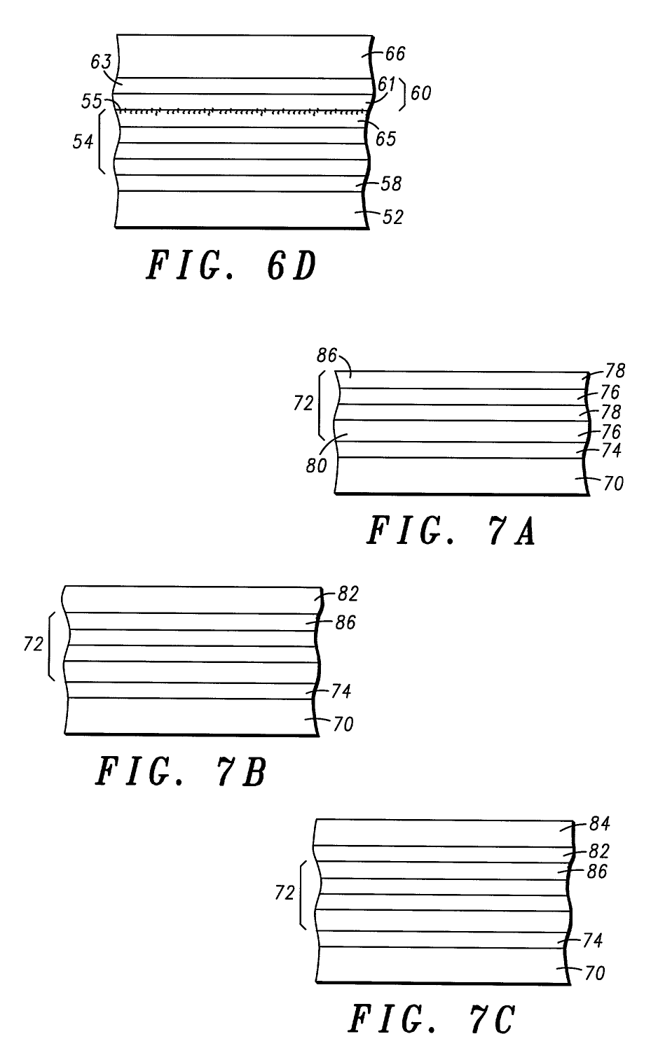

FIGS. 7A-7C schematically illustrate, in cross-section, the formation of another embodiment of a device structure in accordance with the invention. This embodiment includes a compliant layer that functions as a transition layer that uses calthrate or Zintl type bonding. More specifically, this embodiment utilizes an intermetallic template layer to reduce the surface energy of the interface between material layers thereby allowing for two dimensional layer by layer growth.

The structure illustrated in FIG. 7A includes a monocrystalline substrate 70, an amorphous layer 74, and a perovskite stack 72. Amorphous intermediate layer 74 is grown on substrate 70 at the interface between substrate 70 and a first layer 80 of perovskite stack 72 as previously described with reference to FIGS. 3 and 4. Perovskite stack 72 is formed of first accommodating layers 76 and second accommodating layers 78. While FIGS. 7A-7C illustrate a perovskite stack having four layers, it should be understood that perovskite stack 72 may have any number of layers suitable for a desired device application. First accommodating layers 76 and second accommodating layers 78 may comprise any of those materials previously described with reference to first accommodating layer 4 and first accommodating layers 20 and second accommodating layer 5 and second accommodating layers 22 in FIGS. 1-4. Substrate 70 is preferably silicon but may also comprise any of those material previously described with reference to substrate 2 and substrate 12 in FIGS. 1-4.

A template layer 82 is deposited over perovskite stack 72 as illustrated in FIG. 7B and preferably comprises a thin layer of Zintl type phase material composed of metals and metalloids having a great deal of ionic character. A Zintl phase is a compound made of an electropositive element and an electronegative element. The electropositive element provides electrons to the electronegative elements which control the covalent network. As in previously described embodiments, template layer 82 is deposited by way of MBE, CVD, MOCVD, MEE, ALE, PVD, CSD, PLD, or the like to achieve a thickness of one monolayer. Template layer 82 functions as a “soft” layer with non-directional bonding but high crystallinity which absorbs stress build up between layers having lattice mismatch. Materials for template 82 may include, but are not limited to, materials containing Si, Ga, In, and Sb such as, for example, SrAl₂, (MgCaYb)Ga₂, (Ca,Sr,Eu,Yb)In₂, BaGe₂As, and SrSn₂As₂.

A monocrystalline material layer 84 is epitaxially grown over template layer 82 to achieve the final structure illustrated in FIG. 7C. As a specific example, an SrAl₂ layer may be used as template layer 82 and an appropriate monocrystalline material layer 84 such as a compound semiconductor material GaAs is grown over the SrAl₂. The Al—Ti (from the last layer 86 of perovskite stack 72 formed of Sr_{z}Ba_{1-z}TiO₃, where z ranges from 0 to 1) bond is mostly metallic while the Al—As (from the GaAs layer) bond is weakly covalent. The Sr participates in two distinct types of bonding with part of its electric charge going to the oxygen atoms in the last layer 86 of perovskite stack 72 comprising Sr_{z}Ba_{1-z}TiO₃ to participate in ionic bonding and the other part of its valence charge being donated to Al in a way that is typically carried out with Zintl phase materials. The amount of charge transfer depends on the relative electronegativity of elements comprising the template layer 82 as well as on the interatomic distance. In this example, Al assumes an sp³ hybridization and can readily form bonds with monocrystalline material layer 84, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming high quality monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By use of this type of substrate, a relatively inexpensive “handle” wafer overcomes the fragile nature of compound semiconductor and other monocrystalline material layers by placing them over a relatively more durable and easy to fabricate base material. In addition, this “handle” wafer serves to reduce defect density in the monocrystalline material layer and to reduce Schottky leakage current from the substrate to the monocrystalline material layer.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, solution to occur or become more pronounced are not to be constructed as critical, required, or essential features or elements of any or all of the claims. As used, herein, the terms “comprises,” “comprising” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
a perovskite stack overlying said substrate, wherein said perovskite stack comprises:
a first accommodating layer formed of a first monocrystalline perovskite oxide material having a first lattice constant; and
a second accommodating layer formed of a second monocrystalline perovskite oxide material having a second lattice constant, wherein said first lattice constant is different from said second lattice; and
a monocrystalline material layer overlying said perovskite stack,
wherein a strain is effected at least at one of an interface between said perovskite stack and said substrate, an interface between said perovskite stack and said monocrystalline material layer, and an interface between said first and said second accommodating layers, and wherein said strain reduces defects in said monocrystalline material layer.

2. The semiconductor structure of claim 1 wherein the monocrystalline material layer comprises a compound semiconductor.

3. The semiconductor structure of claim 1 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

4. The semiconductor structure of claim 1 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

5. The semiconductor structure of claim 1, wherein said substrate comprises silicon.

6. The semiconductor structure of claim 1, wherein said substrate comprises a (001) semiconductor material having an orientation from about 2 degrees to about 6 degrees offset toward the (110) direction.

7. The semiconductor structure of claim 1 wherein at least one of the first and second accommodating layers comprise a material selected from one of: alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

8. The semiconductor structure of claim 1, wherein said first accommodating layer comprises SrₓBa₁₋ₓTiO₃, wherein x ranges from 0 to 1.

9. The semiconductor structure of claim 8, wherein said second accommodating layer comprises Sr_{y}Ba_{1-y}TiO₃, where y is not equal to x.

10. The semiconductor structure of claim 1, further comprising an amorphous oxide interface layer formed between said substrate and said first accommodating layer.

11. The semiconductor structure of claim 1, further comprising a template layer formed overlying said second accommodating layer and underlying said monocrystalline material layer.

12. The semiconductor structure of claim 11, wherein said template layer comprises a Zintl-type phase material.

13. The semiconductor structure of claim 12, wherein said Zintl-type phase material comprises at least one of SrAl₂, (MgCaYb)Ga₂, (Ca, Sr, Eu, Yb)In₂, BaGe₂As, and SrSn₂As₂.

14. The semiconductor structure of claim 11, wherein said template layer comprises a surfactant material.

15. The semiconductor structure of claim 14, wherein said surfactant material comprises at least one of Al, Bi, In, and Ga.

16. The semiconductor structure of claim 14, wherein said template layer further comprises a capping layer.

17. The semiconductor structure of claim 16, wherein said capping layer is formed by exposing the surfactant material to a cap-inducing material.

18. The semiconductor structure of claim 17, wherein said cap-inducing material comprises at least one of As, P, Sb, and N.

19. The semiconductor structure of claim 1, wherein said first accommodating layer has a thickness in the range of from about 4 angstroms to about 50 angstroms.

20. The semiconductor structure of claim 19, wherein said first accommodating layer has a thickness in the range of from about 8 angstroms to about 20 angstroms.

21. The semiconductor structure of claim 1, wherein said second accommodating layer has a thickness in the range of from about 4 angstroms to about 50 angstroms.

22. The semiconductor structure of claim 21, wherein said second accommodating layer has a thickness in the range of from about 8 angstroms to about 20 angstroms.

23. The semiconductor structure of claim 1, wherein said perovskite stack has a thickness in the range of from about 20 angstroms to about 1000 angstroms.

24. The semiconductor structure of claim 23, wherein said perovskite stack has a thickness in the range of from about 20 angstroms to about 50 angstroms.

25. A semiconductor structure comprising:
a monocrystalline substrate;
a perovskite stack overlying said substrate, wherein said perovskite stack comprises:
a first accommodating layer formed of a first monocrystalline perovskite oxide material having a first lattice constant; and
a second accommodating layer formed of a second monocrystalline perovskite oxide material having a second lattice constant, wherein said first lattice constant is different from said second lattice;
a monocrystalline buffer layer overlying said perovskite stack; and
a monocrystalline material layer overlying said monocrystalline buffer layer,
wherein a strain is effected at least at one of an interface between said perovskite stack and said substrate, an interface between said perovskite stack and said monocrystalline buffer layer, and an interface between said first and said second accommodating layers, and wherein said strain reduces defects in said monocrystalline material layer.

26. The semiconductor structure of claim 25 wherein the monocrystalline material layer comprises a compound semiconductor.

27. The semiconductor structure of claim 25 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

28. The semiconductor structure of claim 25 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

29. The semiconductor structure of claim 25, wherein said substrate comprises silicon.

30. The semiconductor structure of claim 25, wherein said substrate comprises a (001) semiconductor material having an orientation from about 2 degrees to about 6 degrees offset toward the (110) direction.

31. The semiconductor structure of claim 25 wherein at least one of the first and second accommodating layers comprise a material selected from one of: alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

32. The semiconductor structure of claim 25, wherein said first accommodating layer comprises SrₓBa₁₋ₓTiO₃, wherein x ranges from 0 to 1.

33. The semiconductor structure of claim 32, wherein said second accommodating layer comprises Sr_{y}Ba_{1-y}TiO₃, where y is not equal to x.

34. The semiconductor structure of claim 25, further comprising an amorphous oxide interface layer formed between said substrate and said first accommodating layer.

35. The semiconductor structure of claim 25, further comprising a template layer formed overlying said monocrystalline buffer layer and underlying said monocrystalline material layer.

36. The semiconductor structure of claim 35, wherein said template layer comprises a Zintl-type phase material.

37. The semiconductor structure of claim 36, wherein said Zintl-type phase material comprises at least one of SrAl₂, (MgCaYb)Ga₂, (Ca, Sr, Eu, Yb)In₂, BaGe₂As, and SrSn₂As₂.

38. The semiconductor structure of claim 35, wherein said template layer comprises a surfactant material.

39. The semiconductor structure of claim 38, wherein said surfactant material comprises at least one of Al, Bi, In, and Ga.

40. The semiconductor structure of claim 38, wherein said template layer further comprises a capping layer.

41. The semiconductor structure of claim 40, wherein said capping layer is formed by exposing the surfactant material to a cap-inducing material.

42. The semiconductor structure of claim 41, wherein said cap-inducing material comprises at least one of As, P, Sb, and N.

43. The semiconductor structure of claim 21, wherein said first accommodating layer has a thickness in the range of from about 4 angstroms to about 50 angstroms.

44. The semiconductor structure of claim 43, wherein said first accommodating layer has a thickness in the range of from about 8 angstroms to about 20 angstroms.

45. The semiconductor structure of claim 25, wherein said second accommodating layer has a thickness in the range of from about 4 angstroms to about 50 angstroms.

46. The semiconductor structure of claim 45, wherein said second accommodating layer has a thickness in the range of from about 8 angstroms to about 20 angstroms.

47. The semiconductor structure of claim 25, wherein said perovskite stack has a thickness in the range of from about 20 angstroms to about 1000 angstroms.

48. The semiconductor structure of claim 47, wherein said perovskite stack has a thickness in the range of from about 40 angstroms to about 80 angstroms.

49. A semiconductor structure comprising:
a monocrystalline substrate;
a perovskite stack overlying said substrate, wherein said perovskite stack comprises alternating first layers formed of a first monocrystalline perovskite oxide material having a first lattice constant and second layers formed of a second monocrystalline perovskite oxide material having a second lattice constant, wherein said first lattice constant is different from said second lattice constant; and
a monocrystalline material layer overlying said perovskite stack,
wherein a strain is effected at least at one of an interface between said perovskite stack and said substrate, an interface between said perovskite stack and said monocrystalline material layer, and an interface between one of said first layers and one of said second layers, and wherein said strain reduces defects in said monocrystalline material layer.

50. The semiconductor structure of claim 49 wherein the monocrystalline material layer comprises a compound semiconductor.

51. The semiconductor structure of claim 49 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

52. The semiconductor structure of claim 49 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

53. The semiconductor structure of claim 49, wherein said substrate comprises silicon.

54. The semiconductor structure of claim 49, wherein said substrate comprises a (001) semiconductor material having an orientation from about 2 degrees to about 6 degrees offset toward the (110) direction.

55. The semiconductor structure of claim 49 wherein at least one of the first and second perovskite oxide materials comprise a material selected from one of: alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

56. The semiconductor structure of claim 49, wherein said first perovskite oxide material comprises SrₓBa₁₋ₓTiO₃, wherein x ranges from 0 to 1.

57. The semiconductor structure of claim 56, wherein said second perovskite oxide material comprises Sr_{y}Ba_{1-y}TiO₃, where y is not equal to x.

58. The semiconductor structure of claim 49, further comprising an amorphous oxide interface layer formed between said substrate and said perovskite stack.

59. The semiconductor structure of claim 41, further comprising a template layer formed overlying said perovskite stack and underlying said monocrystalline material layer.

60. The semiconductor structure of claim 59, wherein said template layer comprises a Zintl-type phase material.

61. The semiconductor structure of claim 60, wherein said Zintl-type phase material comprises at least one of SrAl₂, (MgCaYb)Ga₂, (Ca, Sr, Eu, Yb)In₂, BaGe₂As, and SrSn₂As₂.

62. The semiconductor structure of claim 59, wherein said template layer comprises a surfactant material.

63. The semiconductor structure of claim 62, wherein said surfactant material comprises at least one of Al, Bi, In, and Ga.

64. The semiconductor structure of claim 62, wherein said template layer further comprises a capping layer.

65. The semiconductor structure of claim 64, wherein said capping layer is formed by exposing the surfactant material to a cap-inducing material.

66. The semiconductor structure of claim 65, wherein said cap-inducing material comprises at least one of As, P, Sb, and N.

67. The semiconductor structure of claim 49, wherein said first layers have a thickness in the range of from about 4 angstroms to about 50 angstroms.

68. The semiconductor structure of claim 67, wherein said first layers have a thickness in the range of from about 8 angstroms to about 20 angstroms.

69. The semiconductor structure of claim 49, wherein said second layers have a thickness in the range of from about 4 angstroms to about 50 angstroms.

70. The semiconductor structure of claim 69, wherein said second layers have a thickness in the range of from about 8 angstroms to about 20 angstroms.

71. The semiconductor structure of claim 49, wherein said perovskite stack has a thickness in the range of from about 20 angstroms to about 1000 angstroms.

72. The semiconductor structure of claim 71, wherein said perovskite stack has a thickness in the range of from about 40 angstroms to about 80 angstroms.

73. A semiconductor structure comprising:
a monocrystalline substrate;
a perovskite stack overlying said substrate, wherein said perovskite stack comprises alternating first layers formed of a first monocrystalline perovskite oxide material having a first lattice constant and second layers formed of a second monocrystalline perovskite oxide material having a second lattice constant, wherein said first lattice constant is different from said second lattice constant;
a monocrystalline buffer layer overlying said perovskite stack; and
a monocrystalline material layer overlying said monocrystalline buffer layer,
wherein a strain is effected at least at one of an interface between said perovskite stack and said substrate, an interface between said perovskite stack and said monocrystalline buffer layer, and an interface between one of said first layers and one of said second layers, and wherein said strain reduces defects in said monocrystalline material layer.

74. The semiconductor structure of claim 73 wherein the monocrystalline material layer comprises a compound semiconductor.

75. The semiconductor structure of claim 73 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

76. The semiconductor structure of claim 73 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

77. The semiconductor structure of claim 73, wherein said substrate comprises silicon.

78. The semiconductor structure of claim 73, wherein said substrate comprises a (001) semiconductor material having an orientation from about 2 degrees to about 6 degrees offset toward the (110) direction.

79. The semiconductor structure of claim 73 wherein at least one of the first and second perovskite oxide materials comprise a material selected from one of: alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

80. The semiconductor structure of claim 73, wherein said first perovskite oxide material comprises SrₓBa₁₋ₓTiO₃, wherein x ranges from 0 to 1.

81. The semiconductor structure of claim 80, wherein said second perovskite oxide material comprises Sr_{y}Ba_{1-y}TiO₃, where y is not equal to x.

82. The semiconductor structure of claim 73, further comprising an amorphous oxide interface layer formed between said substrate and said perovskite stack.

83. The semiconductor structure of claim 73, further comprising a template layer formed overlying said monocrystalline buffer layer and underlying said monocrystalline material layer.

84. The semiconductor structure of claim 83, wherein said template layer comprises a Zintl-type phase material.

85. The semiconductor structure of claim 84, wherein said Zintl-type phase material comprises at least one of SrAl₂, (MgCaYb)Ga₂, (Ca, Sr, Eu, Yb)In₂, BaGe₂As, and SrSn₂As₂.

86. The semiconductor structure of claim 83, wherein said template layer comprises a surfactant material.

87. The semiconductor structure of claim 86, wherein said surfactant material comprises at least one of Al, Bi, In, and Ga.

88. The semiconductor structure of claim 86, wherein said template layer further comprises a capping layer.

89. The semiconductor structure of claim 88, wherein said capping layer is formed by exposing the surfactant material to a cap-inducing material.

90. The semiconductor structure of claim 89, wherein said cap-inducing material comprises at least one of As, P, Sb, and N.

91. The semiconductor structure of claim 73, wherein said first layers have a thickness in the range of from about 4 angstroms to about 50 angstroms.

92. The semiconductor structure of claim 91, wherein said first layers have a thickness in the range of from about 8 angstroms to about 20 angstroms.

93. The semiconductor structure of claim 73, wherein said second layers have a thickness in the range of from about 4 angstroms to about 50 angstroms.

94. The semiconductor structure of claim 93, wherein said second layers have a thickness in the range of from about 8 angstroms to about 20 angstroms.

95. The semiconductor structure of claim 73, wherein said perovskite stack has a thickness in the range of from about 20 angstroms to about 1000 angstroms.

96. The semiconductor structure of claim 95, wherein said perovskite stack has a thickness in the range of from about 40 angstroms to about 80 angstroms.

97. A process for fabricating a high quality semiconductor structure exhibiting low Schottky leakage current, said method comprising:
providing a monocrystalline substrate;
epitaxially growing a first accommodating layer on said substrate, wherein said first accommodating layer is formed of a first monocrystalline perovskite oxide material having a first lattice constant;
epitaxially growing a second accommodating layer on said first accommodating layer, wherein said second accommodating layer is formed of a second monocrystalline perovskite oxide material having a second lattice constant, and wherein said first lattice constant is different from said second lattice constant; and
epitaxially growing a monocrystalline material layer overlying said second accommodating layer,
wherein a strain is effected at least at one of an interface between said first accommodating layer and said substrate, an interface between said second accommodating layer and said monocrystalline material layer, and an interface between said first and said second accommodating layers, and wherein said strain reduces defects in said monocrystalline material layer.

98. The process of claim 97 wherein the monocrystalline material layer comprises a compound semiconductor.

99. The process of claim 97 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

100. The process of claim 97 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

101. The process of claim 97 wherein at least one of the epitaxially growing a first and second accommodating layers comprises epitaxially growing a material selected from one of: alkaline earth metal titanates, alkaline earth metal zirconates, alkaline earth metal halfnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

102. The process of claim 97, further comprising forming an amorphous oxide layer between said substrate and said first accommodating layer.

103. The process of claim 97, further comprising epitaxially growing a monocrystalline buffer layer overlying said second accommodating layer and underlying said monocrystalline material layer.

104. The process of claim 97, further comprising forming a template layer overlying said second accommodating layer and underlying said monocrystalline material layer.

105. The process of claim 103, further comprising forming a template layer overlying said monocrystalline buffer layer and underlying said monocrystalline material layer.

106. The process of claim 97, wherein said epitaxially growing a first accommodating layer comprises epitaxially growing a first accommodating layer to a thickness in the range of from about 4 angstroms to about 50 angstroms.

107. The process of claim 106, wherein said epitaxially growing a first accommodating layer comprises epitaxially growing a first accommodating layer to a thickness in the range of from about 8 angstroms to about 20 angstroms.

108. The process of claim 97, wherein said epitaxially growing a second accommodating layer comprises epitaxially growing a second accommodating layer to a thickness in the range of from about 4 angstroms to about 50 angstroms.

109. The process of claim 108, wherein said epitaxially growing a second accommodating layer comprises epitaxially growing a second accommodating layer to a thickness in the range of from about 8 angstroms to about 20 angstroms.

110. A process for fabricating a high quality semiconductor structure exhibiting low Schottky leakage current, said method comprising:
providing a monocrystalline substrate;
epitaxially growing alternating first layers and second layers to form a perovskite stack overlying said substrate, wherein said first layers are formed of a first monocrystalline perovskite oxide material having a first lattice constant and said second layers are formed of a second monocrystalline perovskite oxide material having a second lattice constant that is different from said first lattice constant; and
epitaxially growing a monocrystalline material layer overlying said perovskite stack,
wherein a strain is effected at least at one of an interface between said perovskite stack and said substrate, an interface between said perovskite stack and said monocrystalline material layer, and an interface between one of said first and one of said second layers, and wherein said strain reduces defects in said monocrystalline material layer.

111. The process of claim 110 wherein the monocrystalline material layer comprises a compound semiconductor.

112. The process of claim 110 wherein the monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

113. The process of claim 110 wherein the monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, lead sulfide selenide, lead selenide, lead telluride, lead sulfide selenide.

114. The process of claim 110, further comprising forming an amorphous oxide layer between said substrate and said perovskite stack.

115. The process of claim 110, further comprising epitaxially growing an additional buffer layer overlying said perovskite stack and underlying said monocrystalline material layer.

116. The process of claim 110, further comprising forming a template layer overlying said perovskite stack and underlying said monocrystalline material layer.

117. The process of claim 115, further comprising forming a template layer overlying said additional buffer layer and underlying said monocrystalline material layer.

118. The process of claim 110, wherein said epitaxially growing alternating first layers and second layers comprises epitaxially growing first layers to a thickness in the range of from about 4 angstroms to about 50 angstroms.

119. The process of claim 118, wherein said epitaxially growing first layers comprises epitaxially growing first layers to a thickness in the range of from about 8 angstroms to about 20 angstroms.

120. The process of claim 110, wherein said epitaxially growing alternating first layers and second layers comprises epitaxially growing second layers to a thickness in the range of from about 4 angstroms to about 50 angstroms.

121. The process of claim 120, wherein said epitaxially growing second layers comprises epitaxially growing second layers to a thickness in the range of from about 8 angstroms to about 20 angstroms.

122. A process for fabricating a semiconductor structure comprising:
providing a monocrystalline silicon substrate having a first lattice constant;
selecting a first material that when properly oriented has a second lattice constant and crystalline structure such that the first material can be deposited as a monocrystalline film overlying the monocrystalline silicon substrate, the second lattice constant being different than the first lattice constant;
depositing a first monocrystalline film of the first material overlying the monocrystalline silicon substrate, the film having a thickness less than a thickness of the material that would result in strain-induced defects, the monocrystalline film being strained because the first lattice constant is different than the second lattice constant;
forming an amorphous interface layer at an interface between the first monocrystalline film and the monocrystalline silicon substrate, the amorphous interface layer having a thickness sufficient to relieve the strain in the first monocrystalline film;
selecting a second material that when properly oriented has a third lattice constant and crystalline structure such that the second material can be deposited as a monocrystalline film overlying the first monocrystalline film, the third lattice constant being different than the second lattice constant;
depositing a second monocrystalline film of the second material overlying the first monocrystalline film;
selecting a compound semiconductor material having a fourth lattice constant that is different from the first lattice constant and that when properly oriented can be deposited on the second monocrystalline film as a monocrystalline compound semiconductor material; and
epitaxially depositing a monocrystalline layer of the compound semiconductor material overlying the second monocrystalline film;
wherein the second lattice constant is selected to be intermediate to the first and fourth lattice constants.

123. The process of claim 122 wherein the third lattice constant is different than the first lattice constant.

124. The process of claim 122 further comprising the step of forming a first template layer overlying the monocrystalline substrate to nucleate the step of depositing a first monocrystalline film.

125. The process of claim 124 further comprising the step of forming a second template layer overlying the second monocrystalline film to nucleate the step of epitaxially depositing a compound semiconductor layer.

126. The process of claim 122 wherein at least one of providing a first and a second monocrystalline oxide layer comprises providing a monocrystalline oxide layer comprising a material selected from the group consisting of alkaline-earth-metal titanates, alkaline-earth-metal zirconates, alkaline-earth-metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide.

127. The process of claim 125 wherein the process of forming the second template layer comprises capping the monocrystalline oxide layer with about 1-10 monolayers of a material M—N or M—O—N wherein M is selected from the group consisting of Zr, Hf, Sr, and Ba and N is selected from the group consisting of As, P, Ga, Al, and In.

128. The process of claim 127 wherein the step of epitaxially growing a monocrystalline compound semiconductor layer comprises epitaxially growing a layer comprising a material selected from InP and InGaAs.

129. The process of claim 128 further comprising forming a buffer layer comprising a superlattice comprising InGaAs overlying the template.

130. The process of claim 122 wherein the step of providing a first monocrystalline oxide layer comprises epitaxially growing a monocrystalline oxide layer lattice matched to an underlying monocrystalline silicon substrate.

131. The process of claim 122 wherein the step of providing a first monocrystalline oxide layer comprises providing an oxide layer comprising SrₓBa₁₋ₓTiO₃ where x ranges from 0 to 1.

132. The process of claim 131 wherein the step of epitaxially growing a monocrystalline compound semiconductor layer comprises epitaxially depositing a layer selected from GaAs, AlGaAs, GaAsP, and GaInP.

133. A process for fabricating a semiconductor structure comprising:
providing a moncrystalline silicon substrate;
depositing a first monocrystalline perovskite oxide film with a first lattice constant overlying the monocrystalline silicon substrate, the film having a thickness less than a thickness of the material that would result in strain-induced defects;
forming an amorphous oxide interface layer containing at least silicon and oxygen at an interface between the first monocrystalline perovskite oxide film and the monocrystalline silicon substrate;
depositing a second monocrystalline perovskite oxide film with a second lattice constant overlying the first monocrystalline oxide film, wherein said first lattice constant is different from said second lattice constant; and
epitaxially forming a monocrystalline compound semiconductor layer overlying the second monocrystalline perovskite oxide film.

134. The process of claim 133 wherein the monocrystalline silicon substrate is orientated in the (100) direction.

135. The process of claim 133, following the formation of the amorphous oxide interface layer, further comprising continuing to deposit the monocrystalline perovskite oxide film overlying the monocrystalline silicon substrate.

136. The process of claim 133 further comprising forming a first template layer overlying the monocrystalline silicon substrate to nucleate depositing the first monocrystalline perovskite oxide film.

137. The process of claim 136 further comprising forming a second template layer overlying the second monocrystalline perovskite oxide film to nucleate epitaxially depositing the monocrystalline compound semiconductor layer.

138. The process of claim 133 wherein at least one of the first and second monocrystalline perovskite oxide films is selected from the group consisting of: alkaline-earth-metal titanates, alkaline-earth-metal zirconates, alkaline-earth-metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide.

139. The process of claim 133 wherein the providing a first monocrystalline perovskite oxide film comprises epitaxially growing a monocrystalline perovskite oxide film lattice-matched to the monocrystalline silicon substrate.

140. The process of claim 133 wherein the first monocrystalline perovskite oxide film comprises SrₓBa₁₋ₓTiO₃ where x ranges from 0 to 1.

141. The process of claim 137 wherein the monocrystalline compound semiconductor layer is selected from the group consisting of: GaAs, AlGaAs, GaAsP, and GaInP.
